(19) United States
(12) Patent Application Publication
(10) Pub. No.: US 2026/0282569 A1
(43) Pub. Date: Sep. 17, 2026

(54) INTEGRATED CHIP AND METHOD OF MANUFACTURING THE SAME

(71) Applicant: Taiwan Semiconductor Manufacturing Company, Ltd., Hsinchu (TW)

(72) Inventors: Yen-Yu Chen, Kaohsiung City (TW); Wen Hsiang Tu, Kaohsiung City (TW); Jen-Cheng Liu, Hsin-Chu City (TW)

(21) Appl. No.: 19/077,313

(22) Filed: Mar. 12, 2025

(51) Int. Cl. H10F 39/00; H01L 23/00; H01L 25/16

(52) U.S. Cl. CPC H10F 39/802; H10F 39/011; H10F 39/809; H10W 90/00; H10W 90/792

(57) ABSTRACT

An integrated chip including a photodetector and a transfer transistor, a source follower transistor, a first overflow transistor, a first LOFIC (lateral overflow integration capacitor), a second overflow transistor, and a second LOFIC. The transfer transistor includes a first source/drain coupled to the photodetector. The source follower transistor includes a first source/drain coupled to a supply voltage terminal, a second source/drain coupled to an output terminal, and a gate coupled to a second source/drain of the transfer transistor. The first overflow transistor includes a first source/drain coupled to the gate of the source follower transistor. The first LOFIC includes a first electrode coupled to a second source/drain of the first overflow transistor. The second overflow transistor includes a first source/drain coupled to the gate of the source follower transistor. The second LOFIC includes a first electrode coupled to a second source/drain of the second overflow transistor.

### BACKGROUND

Complementary metal-oxide semiconductor (CMOS) image sensors are used in a wide range of modern-day electronic devices, such as, for example, cameras, tablets, smart phones, and so on. CMOS image sensors may be front-side illuminated (FSI) or back-side illuminated (BSI). Compared to FSI image sensors, BSI image sensors have better sensitivity, better angular response, and greater metal routing flexibility.

Many modern integrated chips include transistors as well as passive devices. Some examples of passive devices include capacitors, resistors, inductors, varactors, etc. Passive devices are widely used to control integrated chip characteristics, such as gains, time constants, etc. Some passive devices include integrated passive devices (IPDs). An IPD is a collection of one or more passive devices embedded into a single monolithic device and packaged as an integrated circuit (IC).

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a circuit diagram of some embodiments of an image sensor integrated chip including a first LOFIC (lateral overflow integration capacitor) and a second LOFIC coupled in parallel.

FIG. 2 illustrates a cross-sectional view of some embodiments of the image sensor integrated chip of FIG. 1.

FIG. 3 illustrates potential diagrams of some embodiments of electron overflow paths of the image sensor integrated chip of FIG. 1.

FIG. 4 illustrates a circuit diagram of some embodiments of the image sensor integrated chip of FIG. 1, further including a third LOFIC coupled in parallel with the first LOFIC and the second LOFIC.

FIG. 5 illustrates a cross-sectional view of some embodiments of the image sensor integrated chip of FIG. 4.

FIG. 6 illustrates a circuit diagram of some embodiments of the image sensor integrated chip of FIG. 1.

FIG. 7 illustrates a cross-sectional view of some embodiments of the image sensor integrated chip of FIG. 6.

FIG. 8 illustrates a circuit diagram of some embodiments of the image sensor integrated chip of FIG. 1, further including a reset transistor coupled to the first LOFIC and the second LOFIC.

FIG. 9 illustrates a cross-sectional view of some embodiments of the image sensor integrated chip of FIG. 8.

FIG. 10 illustrates a circuit diagram of some embodiments of the image sensor integrated chip of FIG. 1, further including a first reset transistor coupled to the first LOFIC and a second reset transistor coupled to the second LOFIC.

FIG. 11 illustrates a cross-sectional view of some embodiments of the image sensor integrated chip of FIG. 10.

FIGS. 12-16 illustrate cross-sectional views of various embodiments of the image sensor integrated chips of any of FIGS. 1-11.

FIG. 17 illustrates a series of potential diagrams of some embodiments of an operation of the image sensor integrated chip of FIG. 1.

FIGS. 18-23 illustrate cross-sectional views of some embodiments of a method of forming an image sensor integrated chip including a first LOFIC and a second LOFIC coupled in parallel.

FIG. 24 illustrates a flow diagram of some embodiments of a method of forming an image sensor integrated chip including a first LOFIC and a second LOFIC coupled in parallel.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An image sensor integrated chip includes a plurality of pixels. A pixel includes a photodetector, a floating node, a transfer transistor selectively coupling the photodetector to the floating node, and a source follower transistor having a gate electrode coupled to the floating node. In some image sensors, the pixel further includes a LOFIC (lateral overflow integration capacitor) and an overflow transistor selectively coupling the LOFIC to the floating node. The LOFIC accumulates overflow electrons from the photodetector and the floating node to improve a dynamic range of the pixel.

A challenge with some image sensors is that there is limited space for the LOFIC within the pixel. Thus, the size of the LOFIC is limited and consequently the overflow electron storage capacity of the LOFIC (e.g., the capacitance of the LOFIC) is limited. As a result, the dynamic range of the pixel may be limited.

In various embodiments of the present disclosure, the pixel includes a plurality of LOFICs coupled in parallel. By coupling the LOFICs in parallel, the total overflow electron storage capacity (e.g., the total capacitance) in the pixel can be increased and thus the dynamic range of the pixel can be increased. For example, because space is limited within the pixel, there may not be space for a single larger LOFIC, but there may be space for multiple smaller LOFICs coupled in parallel.

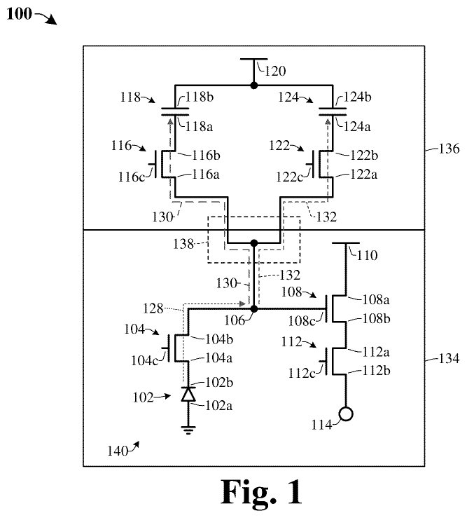

FIG. 1 illustrates a circuit diagram 100 of some embodiments of an image sensor integrated chip including a first LOFIC 118 and a second LOFIC 124 coupled in parallel.

The image sensor integrated chip includes a pixel 140. The pixel 140 includes a photodetector 102 (e.g., a photodiode) and a transfer transistor 104 on a first semiconductor chip 134. The photodetector 102 includes an anode 102a (e.g., a first terminal) and a cathode 102b (e.g., a second terminal). The transfer transistor 104 includes a first source/drain 104a (e.g., a first terminal), a second source/drain 104b (e.g., a second terminal), and a gate 104c (e.g., a control terminal). Source/drain 104a of the transfer transistor 104 is coupled to the cathode 102b of the photodetector 102. Source/drain 104b of the transfer transistor 104 is coupled to a floating node 106. The transfer transistor 104 selectively couples the photodetector 102 to the floating node 106 based on the signal provided to the gate 104c of the transfer transistor 104.

A source follower transistor 108 is on the first semiconductor chip 134. The source follower transistor 108 includes a first source/drain 108a, a second source/drain 108b, and a gate 108c. Source/drain 108a of the source follower transistor 108 is coupled to a supply voltage terminal 110. Gate 108c of the source follower transistor 108 is coupled to the floating node 106.

A select transistor 112 is on the first semiconductor chip 136. The select transistor 112 includes a first source/drain 112a, a second source/drain 112b, and a gate 112c. Source/drain 112a of the select transistor 112 is coupled to source/drain 108b of the source follower transistor 108. Source/drain 112b of the select transistor 112 is coupled to an output terminal 114.

The image sensor integrated chip includes a second semiconductor chip 136 bonded to the first semiconductor chip 134. A first overflow transistor 116 and the first LOFIC 118 are on the second semiconductor chip 136. The first overflow transistor 116 includes a first source/drain 116a, a second source/drain 116b, and a gate 116c. The first LOFIC 118 includes a first electrode 118a (e.g., a first terminal) and a second electrode 118b (e.g., a second terminal). Source/drain 116a of the first overflow transistor 116 is coupled to the floating node 106. Source/drain 116b of the first overflow transistor 116 is coupled to the first electrode 118a of the first LOFIC 118. The first overflow transistor 116 selectively couples the first LOFIC 118 to the floating node 106 based on the signal (e.g., voltage) at the gate 116c of the first overflow transistor 116. The second electrode 118b of the first LOFIC 118 is coupled to a reference voltage terminal 120.

A second overflow transistor 122 and the second LOFIC 124 are on the second semiconductor chip 136. The second overflow transistor 122 includes a first source/drain 122a, a second source/drain 122b, and a gate 122c. The second LOFIC 124 includes a first electrode 124a and a second electrode 124b. Source/drain 122a of the second overflow transistor 122 is coupled to the floating node 106. Source/drain 122b of the second overflow transistor 122 is coupled to the first electrode 124a of the second LOFIC 124. The second overflow transistor 122 selectively couples the second LOFIC 124 to the floating node 106 based on the signal (e.g., voltage) at the gate 124c of the second overflow transistor 122. The second electrode 124b of the second LOFIC 124 is coupled to the second electrode 118b of the first LOFIC 118.

A conductive bonding structure 138 is at the interface between the first semiconductor chip 134 and the second semiconductor chip 136. The conductive bonding structure 138 couples the overflow transistors 116, 122 to the floating node 106.

By coupling the first LOFIC 118 and the second LOFIC 124 in parallel, the total overflow electron storage capacity (e.g., the total capacitance) in the pixel 140 can be increased. As a result, a dynamic range of the pixel 140 can be improved.

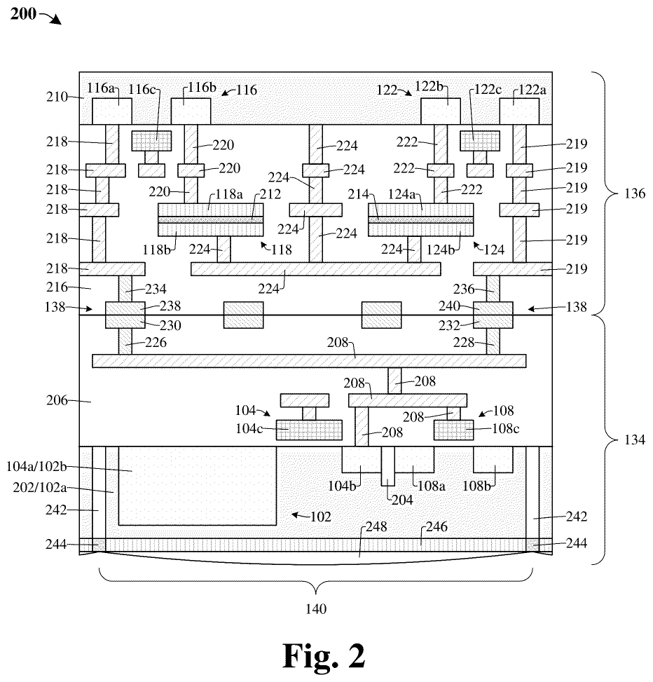

FIG. 2 illustrates a cross-sectional view 200 of some embodiments of the image sensor integrated chip of FIG. 1.

The first semiconductor chip 134 includes a first semiconductor substrate 202. The photodetector 102 and the transfer transistor 104 are disposed along the first semiconductor substrate 202. In some embodiments, anode 102a is formed by the first semiconductor substrate 202, and cathode 102b is formed by source/drain 104a of the transfer transistor 104. In some such embodiments, the first semiconductor substrate 202 is grounded.

The source follower transistor 108 is disposed along the first semiconductor substrate 202 and is laterally spaced from the transfer transistor 104. In some embodiments, an isolation structure 204 (e.g., a shallow trench isolation structure) is between the transfer transistor 104 and the source follower transistor 108. The select transistor 112 (not shown in FIG. 2) is disposed along the first semiconductor substrate 202.

A dielectric structure 206 and conductive interconnects (e.g., conductive contacts, conductive vias, conductive lines, etc.) are on the first semiconductor chip 134. For example, conductive interconnects 208 are within the dielectric structure 206 and couple the gate 108c of the source follower transistor to source/drain 104b of the transfer transistor 104.

The second semiconductor chip 136 includes a second semiconductor substrate 210. The first overflow transistor 116 and the second overflow transistor 122 are disposed along the second semiconductor substrate 210. A dielectric structure 216 is on the second semiconductor chip 136. The first LOFIC 118 and the second LOFIC 124 are within the dielectric structure 216. The first LOFIC 118 includes a dielectric layer 212 between the first electrode 118a and the second electrode 118b. The second LOFIC 124 includes a dielectric layer 214 between the first electrode 124a and the second electrode 124b

Conductive interconnects are on the second semiconductor chip 136. For example, conductive interconnects 218 are within the dielectric structure 216 and coupled to source/drain 116a of the first overflow transistor 116. Conductive interconnects 219 are coupled to source/drain 122a of the second overflow transistor 122. Conductive interconnects 220 couple source/drain 116b of the first overflow transistor 116 to the first electrode 118a of the first LOFIC 118. Conductive interconnects 222 couple source/drain 122b of the second overflow transistor 122 to the first electrode 124a of the second LOFIC 124. Conductive interconnects 224 couple the second electrode 118b of the first LOFIC 118 and the second electrode 124b of the second LOFIC 124 together. In some embodiments, the second semiconductor substrate 210 forms the reference voltage terminal 120, and conductive interconnects 224 couple the second electrode 118b of the first LOFIC 118 and the second electrode 124b of the second LOFIC 124 to the second semiconductor substrate 210 (e.g., conductive interconnects 224 directly contact the second semiconductor substrate 210). In some such embodiments, the second semiconductor substrate 210 is grounded.

The conductive bonding structure 138 couples conductive interconnects 218 and conductive interconnects 219 to conductive interconnects 208. The conductive bonding structure 138 includes conductive bonding contacts 226, 228 on the first semiconductor chip 134, conductive bonding pads 230, 232 on the first semiconductor chip 134, conductive bonding contacts 234, 236 on the second semiconductor chip 136, and conductive bonding pads 238, 240 on the second semiconductor chip 136. Conductive bonding pad 230 and conductive bonding pad 238 are bonded and coupled together at the interface between the first semiconductor chip 134 and the second semiconductor chip 136. Conductive bonding contact 226 couples conductive bonding pad 230 to conductive interconnects 208. Conductive bonding contact 234 couples conductive bonding pad 238 to conductive interconnects 218. Conductive bonding pad 232 and conductive bonding pad 240 are bonded and coupled together at the interface between the first semiconductor chip 134 and the second semiconductor chip 136. Conductive bonding contact 228 couples conductive bonding pad 232 to conductive interconnects 208. Conductive bonding contact 236 couples conductive bonding pad 240 to conductive interconnects 219. Dielectric structure 206 is bonded to dielectric structure 216.

By including multiple LOFICs coupled in parallel in the pixel 140, the total capacitance in the pixel 140 can be increased. For example, because space is limited within the pixel 140, there may not be space for a single larger LOFIC, but there may be space for multiple smaller LOFICs coupled in parallel. Thus, the dynamic range of the pixel 140 can be improved.

In some embodiments, a deep trench isolation structure 242 surrounds the photodetector 102 and isolates the photodetector from neighboring photodetectors (not shown). In some embodiments, a grid structure 244 is over the deep trench isolation structure 242. In some embodiments, a color filter 246 and a micro-lens 248 are over the photodetector 102.

Source/drain(s) may refer to a source or a drain, individually or collectively dependent upon the context. Source/drains may be doped regions of a semiconductor substrate, semiconductor layers over a substrate, or the like. Gates may be referred to as gate electrodes or the like.

In some embodiments, the semiconductor substrates comprise silicon or some other suitable semiconductor. In some embodiments, the dielectric structures comprise a plurality of dielectric layers which comprise silicon oxide, silicon nitride, silicon carbide, hafnium oxide, aluminum oxide, or some other suitable dielectrics. In some embodiments, the gates comprise polysilicon, a metal, or some other suitable material. In some embodiments, the conductive interconnects comprise copper, tungsten, aluminum, titanium, tantalum, or some other suitable material. In some embodiments, the conductive bonding pads and the conductive bonding contacts comprise copper or some other suitable material. In some embodiments, the electrodes of the LOFICs comprise copper, aluminum, titanium nitride, tantalum nitride, or some other suitable material. In some embodiments, the dielectric layers of the LOFICs include a high-k dielectric (e.g., aluminum oxide, hafnium oxide, zirconium oxide, or the like) or some other suitable material. In some embodiments, the supply voltage terminal receives a supply voltage such as, for example, a supply voltage ranging from 1V to 10V or some other suitable supply voltage. In some embodiments, the transistors are metal-oxide-semiconductor field-effect transistors, junction field effect transistors, bipolar junction transistors, fin field-effect transistors, gate all-around field-effect transistors, or some other suitable transistors.

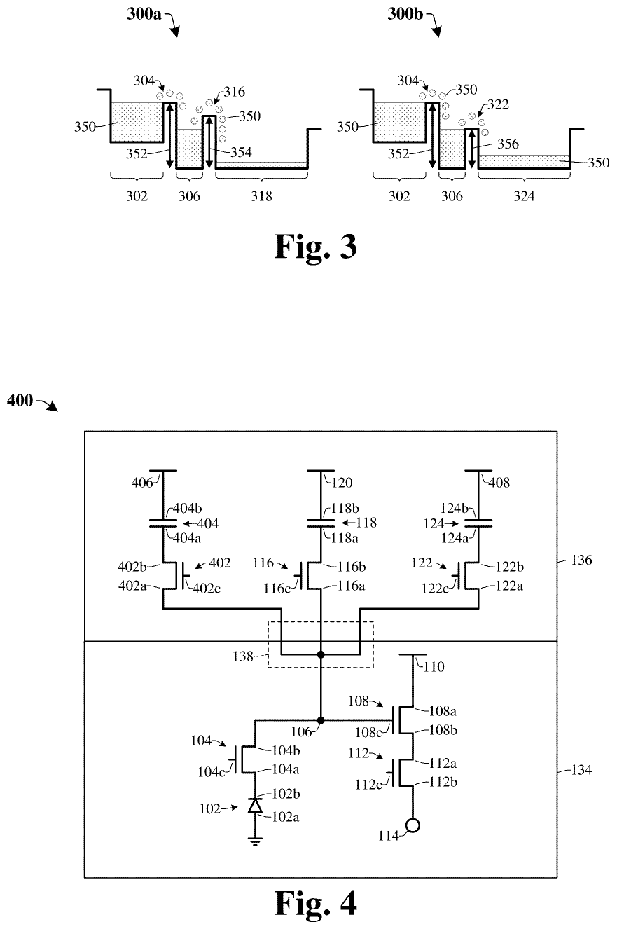

FIG. 3 illustrates a potential diagram 300a of some embodiments of the electron overflow path from the photodetector 102 to the first LOFIC 118 of the image sensor integrated chip of FIG. 1. FIG. 3 further illustrates a potential diagram 300b of some embodiments of the electron overflow path from the photodetector 102 to the second LOFIC 124 of the image sensor integrated chip of FIG. 1.

Referring to FIG. 1 and FIG. 3, the transfer transistor 104 forms a potential barrier 304 between the photodetector electron well 302 (e.g., the electron well formed at the photodetector 102) and the floating node electron well 306 (e.g., the electron well formed at the floating node 106). The first overflow transistor 116 forms a potential barrier 316 between the floating node electron well 306 and the first LOFIC electron well 318 (e.g., the electron well formed at the first LOFIC 118). The second overflow transistor 122 forms a potential barrier 322 between the floating node electron well 306 and the second LOFIC electron well 324 (e.g., the electron well formed at the second LOFIC 124).

During illumination, electrons 350 are generated at the photodetector 102. Electrons 350 can overflow from the photodetector electron well 302 to the floating node electron well 306 along a main stem overflow path 128. Further, electrons 350 can overflow from the floating node electron well 306 to the first LOFIC electron well 318 along a first branch overflow path 130, and from the floating node electron well 306 to the second LOFIC electron well 324 along a second branch overflow path 132.

The potential barrier 304 formed by the transfer transistor 104 has a first height 352. The potential barrier 316 formed by the first overflow transistor 116 has a second height 354 less than the first height 352. The potential barrier 322 formed by the second overflow transistor 122 has a third height 356 less than the first height 352. The heights of the potential barriers can be adjusted by adjusting the voltage at the gates of the transistors forming the potential barriers. For example, the height of potential barrier 304 formed by the transfer transistor 104 can be adjusted by adjusting the voltage at the gate 104c of the transfer transistor 104, the height of potential barrier 316 can be adjusted by adjusting the voltage at the gate 116c of the first overflow transistor 116, and the height of potential barrier 322 can be adjusted by adjusting the voltage at the gate 122c of the second overflow transistor 122. By reducing the voltage at a gate, the height of the corresponding potential barrier can be increased. Conversely, by increasing the voltage at a gate, the height of the corresponding potential barrier can be reduced.

Because the first LOFIC 118 is selectively coupled to the floating node 106 by the first overflow transistor 116, and the second LOFIC 124 is selectively coupled to the floating node 106 by the second overflow transistor 122, the height of potential barrier 316 between the floating node electron well 306 and the first LOFIC electron well 318 (e.g., second height 354) can be set to be different than the height of potential barrier 322 between the floating node electron well 306 and the second LOFIC electron well 324 (e.g., third height 356) so that a different number of electrons flow from the floating node electron well 306 to the first LOFIC electron well 318 than from the floating node electron well 306 to the second LOFIC electron well 324. For example, a higher voltage can be applied to gate 122c, and a lower voltage can be applied to gate 116c so that height 356 of potential barrier 322 is lower than height 354 of potential barrier 316 during illumination. Thus, more electrons can overflow from the floating node electron well 306 to the second LOFIC electron well 324 than from the floating node electron well 306 to the first LOFIC electron well 318. By having different overflow paths with individually controllable potential barrier heights, a control of electron overflow in the pixel 140 can be improved and thus the dynamic range of the pixel 140 can be tuned. As a result, a performance of the pixel 140 can be improved.

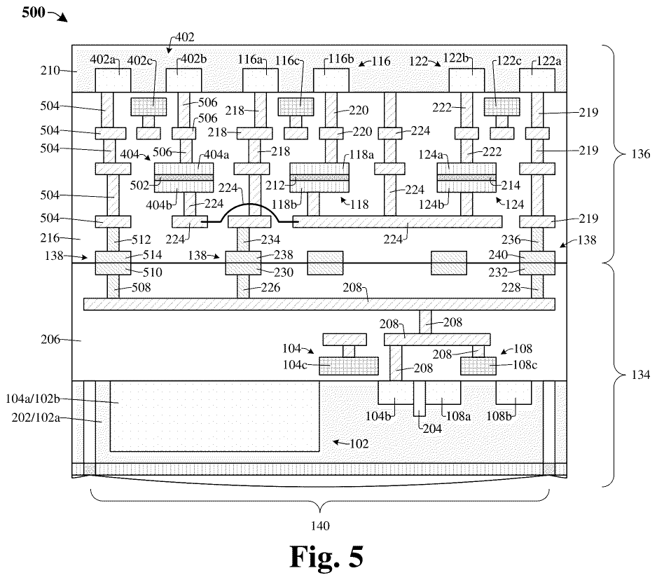

FIG. 4 illustrates a circuit diagram 400 of some embodiments of the image sensor integrated chip of FIG. 1, further including a third LOFIC 404 coupled in parallel with the first LOFIC 118 and the second LOFIC 124. FIG. 5 illustrates a cross-sectional view 500 of some embodiments of the image sensor integrated chip of FIG. 4.

Referring to FIG. 4 and FIG. 5, a third overflow transistor 402 and the third LOFIC 404 are on the second semiconductor chip 136. The third overflow transistor 402 is disposed along the second semiconductor substrate 210. The third overflow transistor 402 includes a first source/drain 402a, a second source/drain 402b, and a gate 402c. The third LOFIC 404 includes a first electrode 404a, a second electrode 404b, and a dielectric layer 502 between the first electrode 404a and the second electrode 404b. Source/drain 402a of the third overflow transistor 402 is coupled to the floating node 106. Source/drain 402b of the third overflow transistor 402 is coupled to the first electrode 404a of the third LOFIC 404. The third overflow transistor 402 selectively couples the third LOFIC 404 to the floating node 106.

In some embodiments, the second electrode 404b of the third LOFIC 404 is coupled to the second electrode 118b of the first LOFIC 118 and the second electrode 124b of the second LOFIC 124. In some other embodiments, the second electrode 118b of the first LOFIC 118 is coupled to reference voltage terminal 120, the second electrode 124b of the second LOFIC 124 is coupled to a reference voltage terminal 408, and the second electrode 404b of the third LOFIC 404 is coupled to a reference voltage terminal 406. In some embodiments, each of the reference voltage terminals 120, 406, 408 are coupled to ground or some other suitable voltage reference.

Conductive interconnects 504 are within the dielectric structure 216 and coupled to source/drain 402a of the third overflow transistor 402. Conductive interconnects 506 couple source/drain 402b of the third overflow transistor 402 to the first electrode 404a of the third LOFIC 404. In some embodiments, conductive interconnects 224 couple the second electrode 404b of the third LOFIC 404 to the second electrode 118b of the first LOFIC, to the second electrode 124b of the second LOFIC 124, and to the second semiconductor substrate 210.

The conductive bonding structure 138 couples conductive interconnects 504 and to conductive interconnects 208. The conductive bonding structure 138 includes conductive bonding contact 508 on the first semiconductor chip 134, conductive bonding pad 510 on the first semiconductor chip 134, conductive bonding contact 512 on the second semiconductor chip 136, and conductive bonding pad 514 on the second semiconductor chip 136. Conductive bonding pad 510 and conductive bonding pad 514 are bonded and coupled together at the interface between the first semiconductor chip 134 and the second semiconductor chip 136. Conductive bonding contact 508 couples conductive bonding pad 510 to conductive interconnects 208. Conductive bonding contact 512 couples conductive bonding pad 514 to conductive interconnects 504.

By including additional LOFICs in the pixel 140, the total capacitance in the pixel 140 can be further increased and thus the dynamic range of the pixel can be further improved. Although three capacitors are illustrated in FIG. 4 and FIG. 5, it will be appreciated that in some embodiments, the pixel can include some other number of LOFICs (e.g., four LOFICs, five LOFICs, etc.) coupled in parallel.

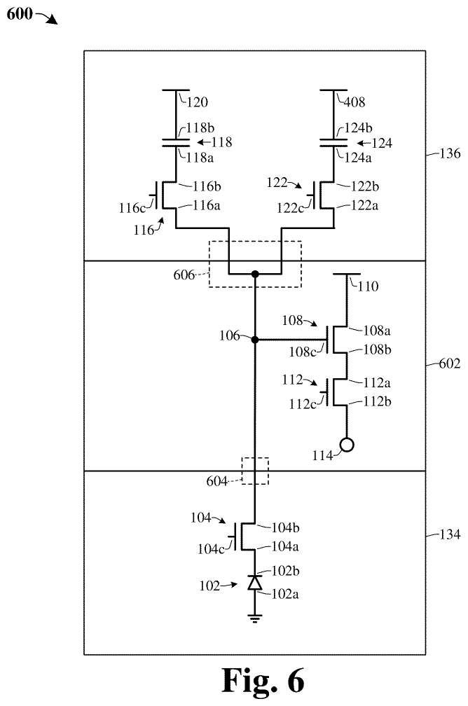

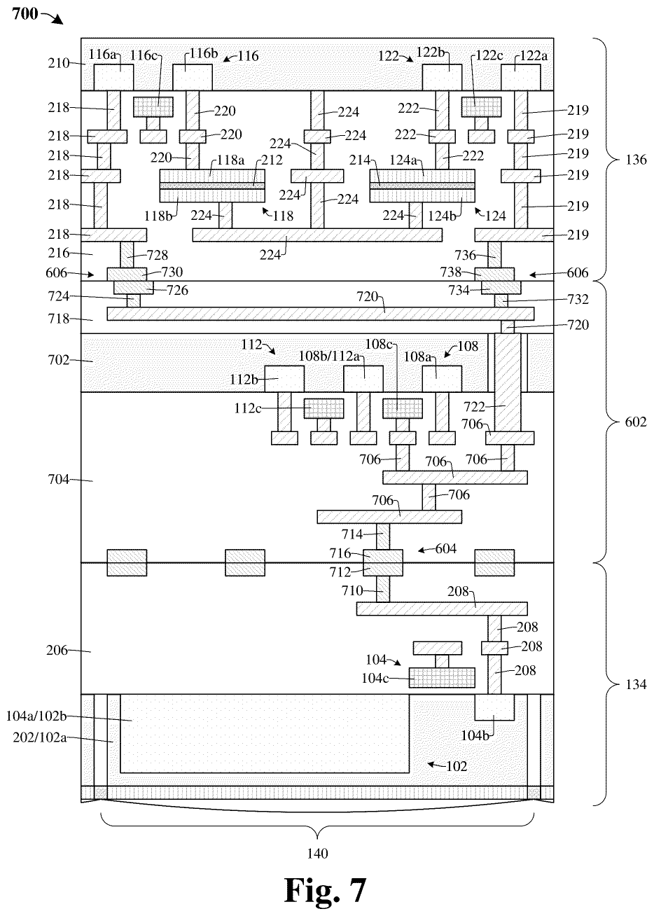

FIG. 6 illustrates a circuit diagram 600 of some embodiments of the image sensor integrated chip of FIG. 1, further including a third semiconductor chip 602. FIG. 7 illustrates a cross-sectional view 700 of some embodiments of the image sensor integrated chip of FIG. 6.

Referring to FIG. 6 and FIG. 7, the third semiconductor chip 602 is bonded between the first semiconductor chip 134 and the second semiconductor chip 136. The source follower transistor 108 and the select transistor 112 are on the third semiconductor chip 602. For example, the third semiconductor chip 602 includes a third semiconductor substrate 702, and the source follower transistor 108 and the select transistor 112 are disposed along the third semiconductor substrate 702. A dielectric structure 704 and conductive interconnects are on the third semiconductor chip 602. For example, conductive interconnects 706 are within the dielectric structure 704 and coupled to the gate 108c of the source follower transistor 108.

A conductive bonding structure 604 is at the interface between the first semiconductor chip 134 and the third semiconductor chip 602 and couples source/drain 104b of the transfer transistor 104 to gate 108c of the source follower transistor 108. For example, the conductive bonding structure 604 couples conductive interconnects 208 to conductive interconnects 706. Conductive bonding structure 604 includes conductive bonding contact 710 on the first semiconductor chip 134, conductive bonding pad 712 on the first semiconductor chip 134, conductive bonding contact 714 on the third semiconductor chip 602, and conductive bonding pad 716 on the third semiconductor chip 602. Conductive bonding pad 712 and conductive bonding pad 716 are bonded and coupled together at the interface between the first semiconductor chip 134 and the third semiconductor chip 602. Conductive bonding contact 710 couples conductive bonding pad 712 to conductive interconnects 208. Conductive bonding contact 714 couples conductive bonding pad 716 to conductive interconnects 706. Dielectric structure 704 is bonded to dielectric structure 206.

A backside dielectric structure 718 is on the third semiconductor chip 602 along a backside of the third semiconductor substrate 702. Conductive interconnects are within the backside dielectric structure 718. A conductive through substrate via 722 extends through the third semiconductor substrate 702 from conductive interconnects 706 to conductive interconnects 720.

A conductive bonding structure 606 is at the interface between the second semiconductor chip 136 and the third semiconductor chip 602 and couples gate 108c of the source follower transistor 108 to source/drain 116a of the first overflow transistor 116 and source/drain 122a of the second overflow transistor 122. For example, conductive bonding structure 606 couples conductive interconnects 720 to conductive interconnects 218 and conductive interconnects 219. Conductive bonding structure 606 includes conductive bonding contacts 728, 736 on the second semiconductor chip 136, conductive bonding pads 730, 738 on the second semiconductor chip 136, conductive bonding contacts 724, 732 on the third semiconductor chip 602, and conductive bonding pads 726, 734 on the third semiconductor chip 602. Conductive bonding pad 726 and conductive bonding pad 730 are bonded and coupled together at the interface between the second semiconductor chip 136 and the third semiconductor chip 602. Conductive bonding contact 724 couples conductive bonding pad 726 to conductive interconnects 720. Conductive bonding contact 728 couples conductive bonding pad 730 to conductive interconnects 218. Conductive bonding pad 734 and conductive bonding pad 738 are bonded and coupled together at the interface between the second semiconductor chip 136 and the third semiconductor chip 602. Conductive bonding contact 732 couples conductive bonding pad 734 to conductive interconnects 720. Conductive bonding contact 736 couples conductive bonding pad 738 to conductive interconnects 219. Dielectric structure 718 is bonded to dielectric structure 216.

By disposing the source follower transistor 108 and the select transistor 112 on a separate chip than the photodetector 102 and the transfer transistor 104, and by disposing the LOFICs and overflow transistors on a separate chip than the source follower transistor 108, the photodetector 102, and the transfer transistor 104, more space can be made available for the photodetector 102. Thus, a size of the pixel can be reduced or a full well capacity of the pixel can be improved.

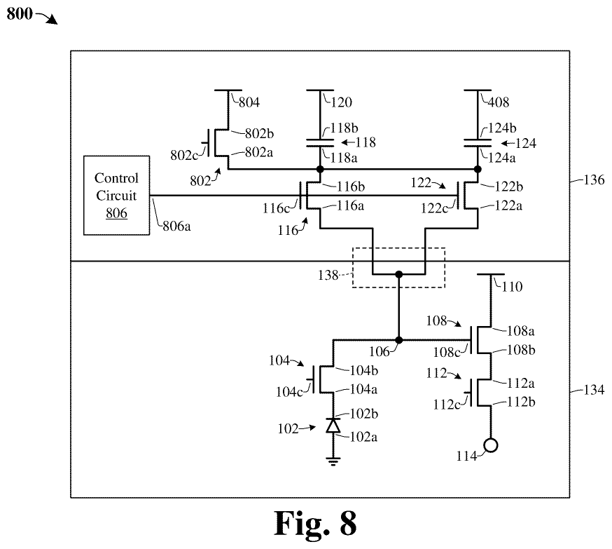

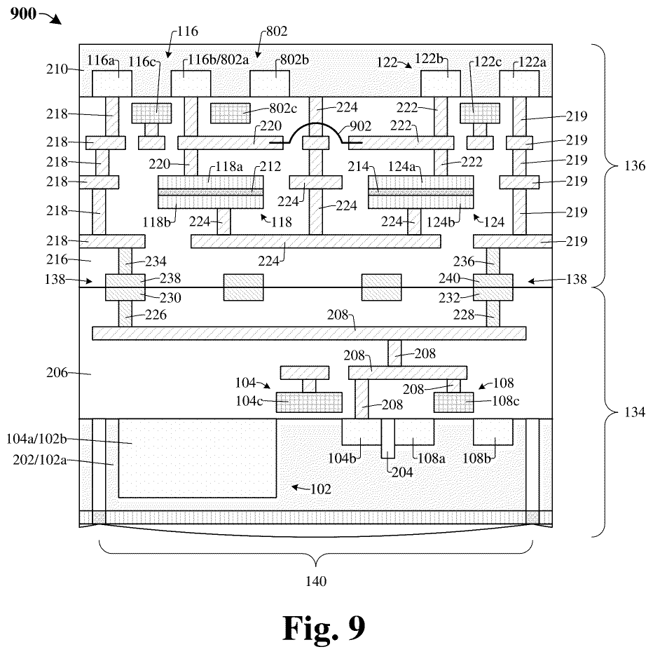

FIG. 8 illustrates a circuit diagram 800 of some embodiments of the image sensor integrated chip of FIG. 1, further including a reset transistor 802 coupled to the first LOFIC 118 and the second LOFIC 124. FIG. 9 illustrates a cross-sectional view 900 of some embodiments of the image sensor integrated chip of FIG. 8.

Referring to FIG. 8 and FIG. 9, the reset transistor 802 is on the second semiconductor chip 136 and disposed along the second semiconductor substrate 210. The reset transistor 802 includes a first source/drain 802a, a second source/drain 802b, and a gate 802c. Source/drain 802a of the reset transistor 802 is coupled to the first electrode 118a of the first LOFIC 118 and the first electrode 124a of the second LOFIC 124. In some embodiments, source/drain 116b forms source/drain 802a (e.g., source/drain 116b and source/drain 802a are one and the same). A conductive interconnect (e.g., illustrated by connection 902) couples source/drain 802a of the reset transistor 802 to source/drain 122b of the second overflow transistor 122 (e.g., by coupling conductive interconnects 220 to conductive interconnects 222). Source/drain 802b of the reset transistor 802 is coupled to a reset voltage terminal 804 (not shown in FIG. 9).

In some embodiments, a control circuit 806 (not shown in FIG. 9) is coupled to the gates of the overflow transistors. For example, the control circuit 806 has an output terminal 806a coupled to gate 116c of the first overflow transistor 116 and gate 122c of the second overflow transistor 122. The control circuit 806 controls the voltages at the gates of the overflow transistors to tune the heights of the potential barriers (e.g., potential barriers 316, 322 of FIG. 3) formed by the overflow transistors to tune the electron overflow paths in the pixel. In some embodiments, the control circuit 806 is on the second semiconductor chip 136. In some other embodiments, the control circuit 806 is on a third semiconductor chip (not shown) bonded to the second semiconductor chip 136.

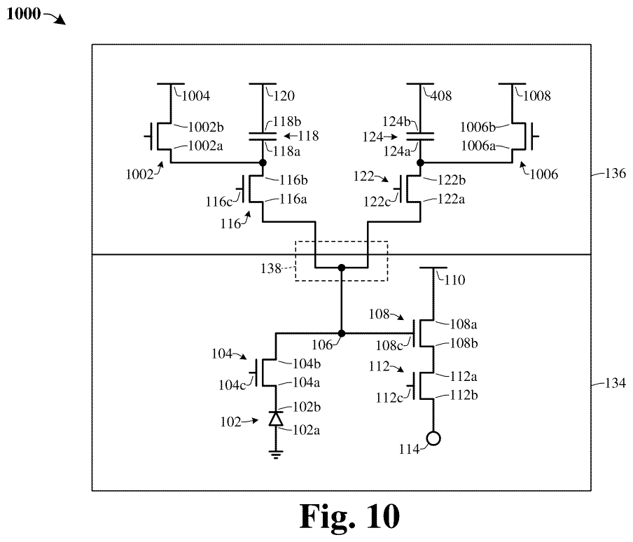

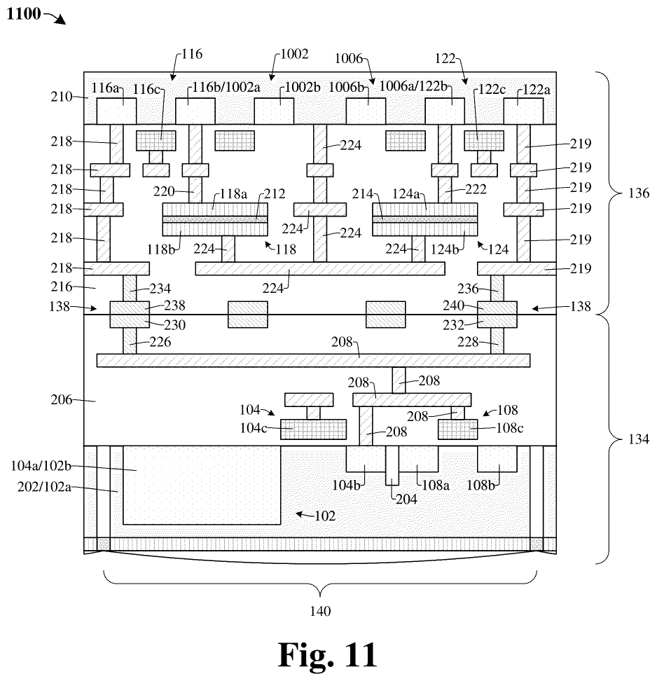

FIG. 10 illustrates a circuit diagram 1000 of some embodiments of the image sensor integrated chip of FIG. 1, further including a first reset transistor 1002 coupled to the first LOFIC 118 and a second reset transistor 1006 coupled to the second LOFIC 124. FIG. 11 illustrates a cross-sectional view 1100 of some embodiments of the image sensor integrated chip of FIG. 10.

Referring to FIG. 10 and FIG. 11, the first reset transistor 1002 and the second reset transistor 1006 are on the second semiconductor chip 136 and disposed along the second semiconductor substrate 210. A first source/drain 1002a of the first reset transistor 1002 is coupled to the first electrode 118a of the first LOFIC 118. A first source/drain 1006a of the second reset transistor 1006 is coupled to the first electrode 124a of the second LOFIC 124. Source/drain 1002b of the first reset transistor 1002 is coupled to a first supply voltage terminal 1004 (not shown in FIG. 9) and source/drain 1006b of the second reset transistor 1006 is coupled to a second reset supply voltage terminal 1008 (not shown in FIG. 9). By having separate reset transistors for the separate LOFICs, the LOFICs can be separately reset. Thus, a control of the pixel can be improved.

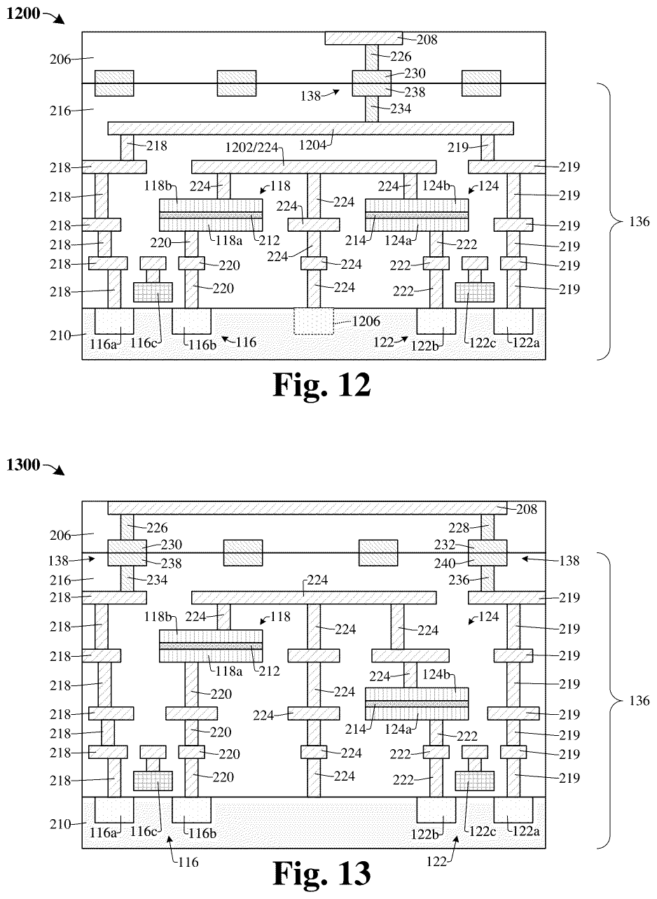

FIGS. 12-16 illustrate cross-sectional views 1200-1600 of various embodiments of the second semiconductor chip 136 of the image sensor integrated chips of any of FIGS. 1-11. The photodetector 102, the transfer transistor 104, and other parts of the first semiconductor chip 134 are not shown in FIGS. 12-16 for simplicity of illustration. Further, the orientation of the second semiconductor chip 136 is flipped in FIGS. 12-16 relative to FIGS. 2, 5, 7, 9, 11.

In some embodiments (e.g., as illustrated in FIG. 12), one or more interconnect layers are between the LOFICs 118, 124 and the top interconnect layer (e.g., the interconnect layer immediately under the conductive bonding contacts). For example, electrode 118b of the first LOFIC 118 and electrode 124b of the second LOFIC 124 are coupled to a conductive line 1202 that is below a top conductive line 1204 on the second semiconductor chip 136. In some such embodiments, top conductive line 1204 couples conductive interconnects 218 to conductive interconnects 219, and conductive bonding contact 234 extends from conductive bonding pad 238 to top conductive line 1204. In some other embodiments (e.g., as illustrated in FIGS. 2, 5, 7, 9, 11), the LOFICs 118, 124 are immediately under the top interconnect layer.

In some embodiments (e.g., as illustrated in FIG. 12), a body contact region 1206 is in the second semiconductor substrate 210 and conductive interconnects 224 are coupled to (e.g., directly contact) the body contact region 1206 to reduce a resistance between the conductive interconnects and the second semiconductor substrate 210. The body contact region 1206 has a same doping type as the second semiconductor substrate 210.

In some embodiments (e.g., as illustrated in FIG. 13), the second LOFIC 124 is on a different interconnect level than the first LOFIC 118. For example, the second LOFIC 124 is under the first LOFIC 118. In some cases, by disposing the LOFICs on different levels within the interconnect, more LOFICs can be fit within the pixel. Thus, a capacitance of the pixel can be increased.

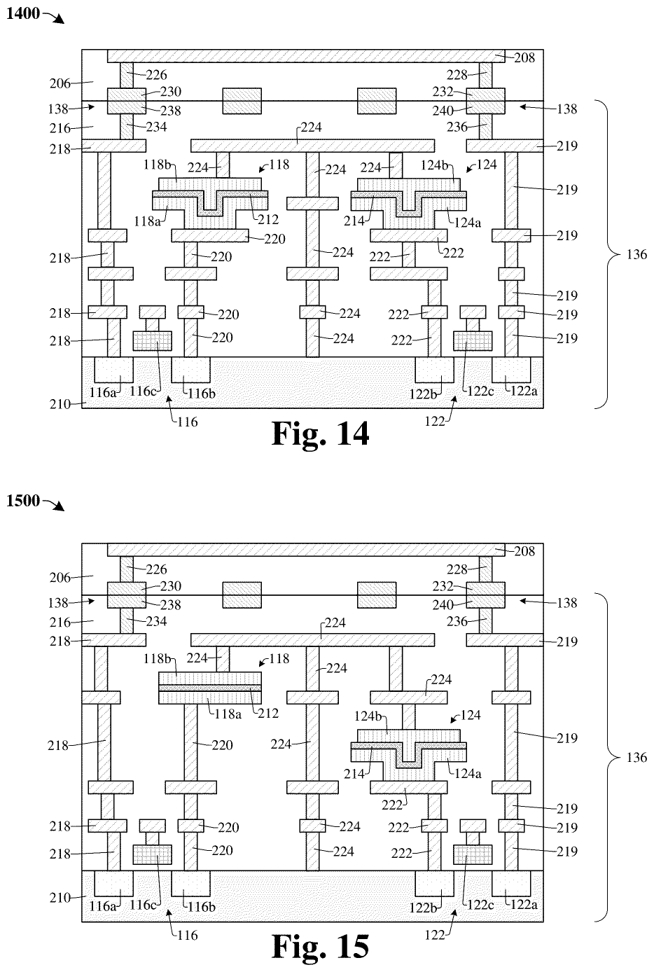

In some embodiments (e.g., as illustrated in FIG. 14), the LOFICs 118, 124 are trench capacitors. In some other embodiments (e.g., as illustrated in FIGS. 2, 5, 7, 9, 11), the LOFICs 118, 124 are planar capacitors (e.g., metal-insulator-metal (MIM) capacitors). In some other embodiments (not shown), the LOFICs 118, 124 are lateral capacitors (e.g., metal-oxide-metal (MOM) capacitors).

In some embodiments (e.g., as illustrated in FIG. 15), the first LOFIC 118 is a different type or style of capacitor than the second LOFIC 124. For example, the first LOFIC 118 is a planar capacitor and the second LOFIC 124 is a trench capacitor. In some cases, by varying the types of the LOFICs in the pixel, more LOFICs can be fit within the pixel. Thus, a capacitance of the pixel can be increased.

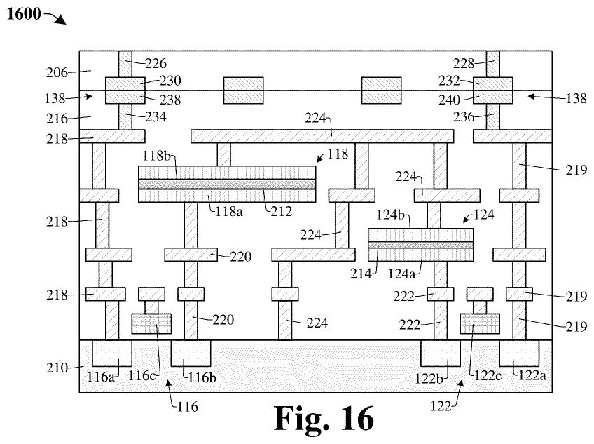

In some embodiments (e.g., as illustrated in FIG. 16), an area between the electrodes of the first LOFIC 118 is different than an area between the electrodes of the second LOFIC 124, and a capacitance of the first LOFIC 118 is different than a capacitance of the second LOFIC 124. For example, an area between the electrodes 118a, 118b of the first LOFIC 118 is greater than an area between the electrodes 124a, 124b of the second LOFIC 124. Further, the capacitance of the first LOFIC 118 is greater than the capacitance of the second LOFIC 124. In some cases, by varying the areas of the LOFICs in the pixel, more LOFICs cab be fit within the pixel. Thus, a capacitance of the pixel can be increased.

In some embodiments (e.g., as illustrated in FIG. 16), the thickness of dielectric layer 212 is different than the thickness of dielectric layer 214. For example, in some embodiments, dielectric layer 212 is thicker than dielectric layer 214. In some embodiments, dielectric layer 212 comprises a first dielectric material and dielectric layer 214 comprises a second dielectric material different than the first dielectric material.

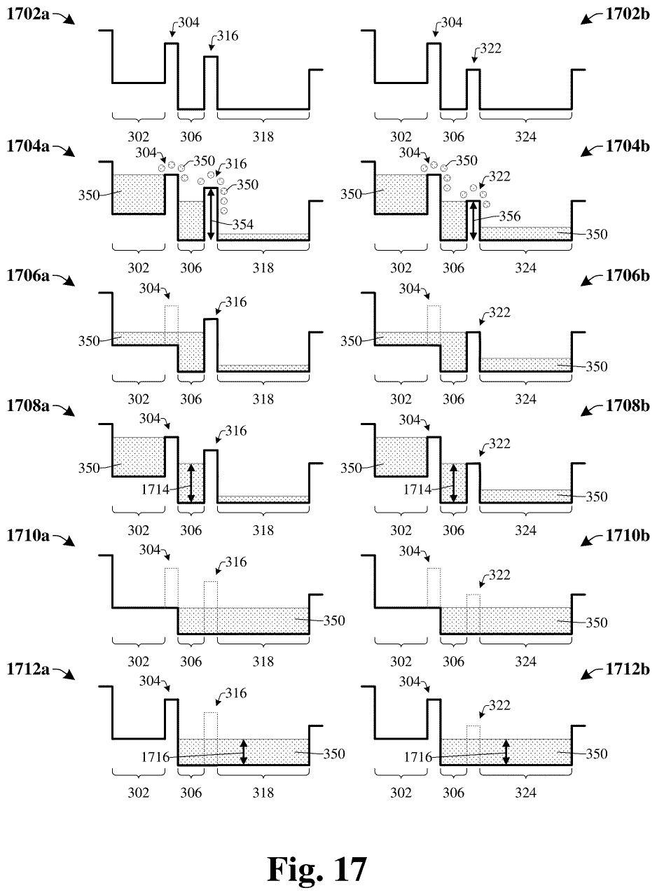

FIG. 17 illustrates a series of potential diagrams of some embodiments of an operation of the image sensor integrated chip of FIG. 1.

Potential diagram 1702a illustrates the electron overflow path from photodetector electron well 302 to the first LOFIC electron well 318 and potential diagram 1702b illustrates the electron overflow path from photodetector electron well 302 to the second LOFIC electron well 324 when the photodetector electron well 302, the floating node electron well 306, the first LOFIC electron well 318, and the second LOFIC electron well 324 are approximately “empty” (e.g., have approximately no charge).

In potential diagram 1704a and potential diagram 1704b, the pixel is illuminated. Electrons 350 fill the photodetector electron well 302, overflow into the floating node electron well 306, fill the floating node electron well 306, and overflow into the first LOFIC electron well 318 and the second LOFIC electron well 324.

In potential diagram 1706a and potential diagram 1706b, electrons 350 are transferred from the photodetector electron well 302 to the floating node electron well 306. For example, the voltage at the gate 104c of the transfer transistor 104 is increased to lower the height of potential barrier 304, thus allowing electrons to more freely flow from the photodetector electron well 302 into the floating node electron well 306.

In potential diagram 1708a and potential diagram 1708b, a first signal 1714 (e.g., a high conversion gain signal) is read based on the charge in the floating node electron well 306.

In potential diagram 1710a and potential diagram 1710b, electrons 350 are transferred from the photodetector electron well 302 and the floating node electron well 306 to the first LOFIC electron well 318 and the second LOFIC electron well 324. For example, the voltage at the gate 104c of the transfer transistor 104 is increased to lower the height of potential barrier 304, the voltage at the gate 116c of the first overflow transistor 116 is increased to lower the height of potential barrier 316, and the voltage at the gate 122c of the second overflow transistor 122 is increased to lower the height of potential barrier 322. Thus, electrons flow between the photodetector electron well 302, the floating node electron well 306, the first LOFIC electron well 318, and the second LOFIC electron well 324.

In potential diagram 1712a and potential diagram 1712b, a second signal 1716 (e.g., a low conversion gain signal) is read based on the charge in the floating node electron well 306, the first LOFIC electron well 318, and the second LOFIC electron well 324.

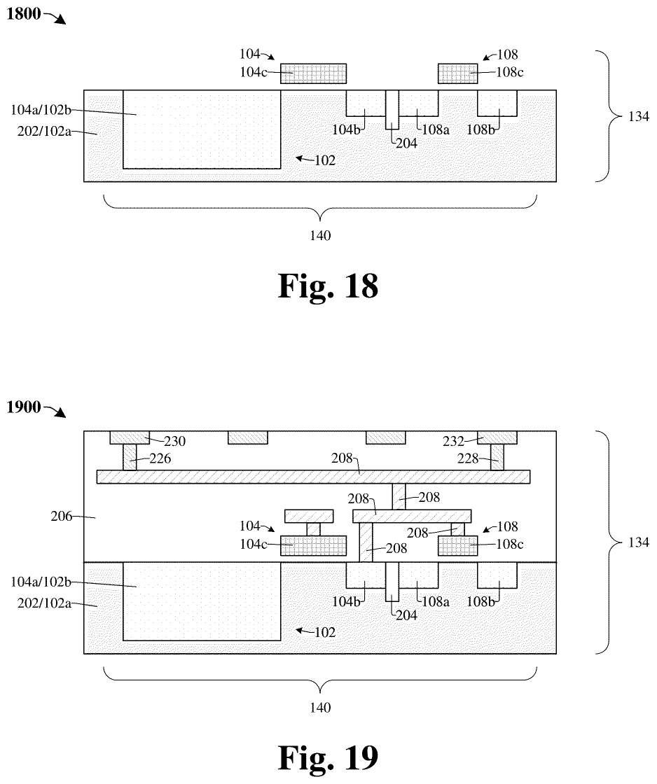

FIGS. 18-23 illustrate cross-sectional views 1800-2300 of some embodiments of a method of forming an image sensor integrated chip including a first LOFIC and a second LOFIC coupled in parallel. Although FIGS. 18-23 are described in relation to a method, it will be appreciated that the structures disclosed in FIGS. 18-23 are not limited to such a method, but instead may stand alone as structures independent of the method.

As shown in cross-sectional view 1800 of FIG. 18, a photodetector 102 and a transfer transistor 104 are formed along the first semiconductor substrate 202. In addition, a source follower transistor 108 and a select transistor 112 (not shown) are formed along the first semiconductor substrate 202.

As shown in cross-sectional view 1900 of FIG. 19, a dielectric structure 206 and conductive interconnects (e.g., conductive contacts, conductive vias, conductive lines, etc.) are formed over the first semiconductor substrate 202. For example, conductive interconnects 208 are formed over the first semiconductor substrate 202 and couple the gate 108c of the source follower transistor to source/drain 104b of the transfer transistor 104. In addition, conductive bonding contacts 226, 228 and conductive bonding pads 230, 232 are formed over conductive interconnects 208.

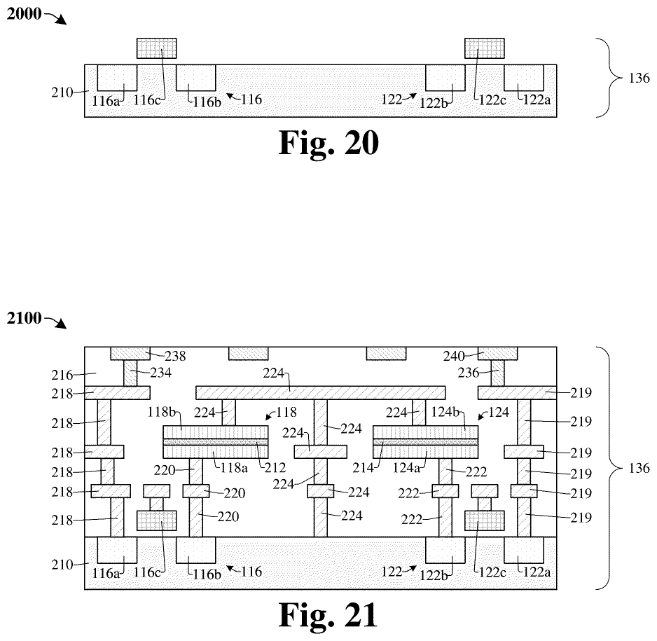

As shown in cross-sectional view 2000 of FIG. 20, a first overflow transistor 116 and a second overflow transistor 122 are formed along a second semiconductor substrate 210.

As shown in cross-sectional view 2100 of FIG. 21, a dielectric structure 216 and conductive interconnects are formed over the second semiconductor substrate 210. Further, the first LOFIC 118 and the second LOFIC 124 are formed over the second semiconductor substrate 210 and within the dielectric structure 216. Conductive interconnects 218 are formed over the second semiconductor substrate 210 and coupled to source/drain 116a of the first overflow transistor 116. Conductive interconnects 219 are formed over the second semiconductor substrate 210 and coupled to source/drain 122a of the second overflow transistor 122. Conductive interconnects 220 are formed over the second semiconductor substrate 210 and couple source/drain 116b of the first overflow transistor 116 to the first electrode 118a of the first LOFIC 118. Conductive interconnects 222 are formed over the second semiconductor substrate 210 and couple source/drain 122b of the second overflow transistor 122 to the first electrode 124a of the second LOFIC 124. Furthermore, conductive bonding contacts 234, 236 and conductive bonding pads 238, 240 are formed over conductive interconnects 218, 219, 220, 222, 224.

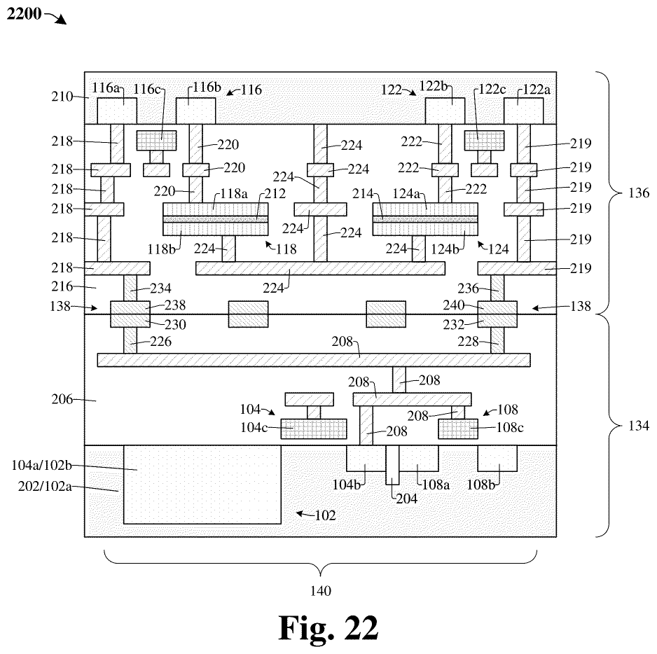

As shown in cross-sectional view 2200 of FIG. 22, the second semiconductor chip 136 and the first semiconductor chip 134 are bonded together. For example, conductive bonding pad 230 and conductive bonding pad 238 are bonded together at the interface between the first semiconductor chip 134 and the second semiconductor chip 136. Further, dielectric structure 206 is bonded to dielectric structure 216. In some embodiments, the bonding comprises a direct bonding process, a fusion bonding process, or some other suitable process.

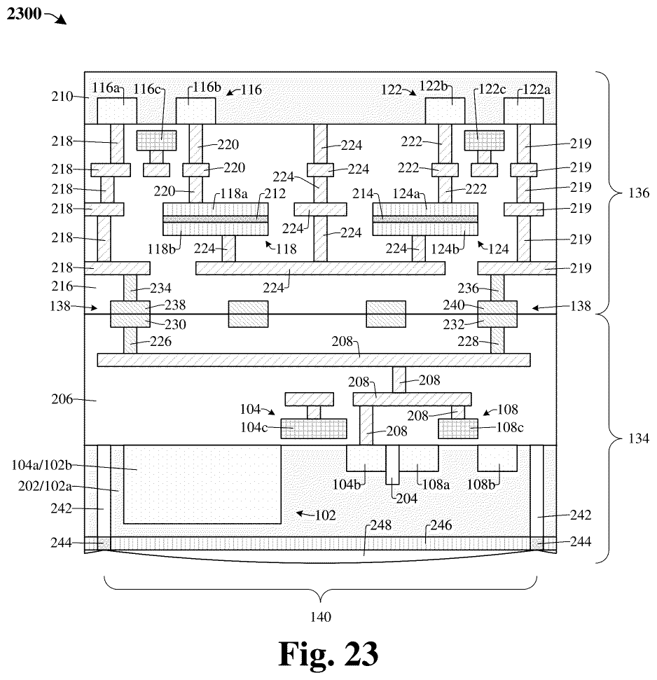

As shown in cross-sectional view 2300 of FIG. 23, a deep trench isolation structure 242 is formed in the first semiconductor substrate 202 surrounding the photodetector 102 and isolating the pixel from neighboring pixels (not shown). A grid structure 244 is formed over the deep trench isolation structure 242. A color filter 246 and a micro-lens 248 are formed over the photodetector 102.

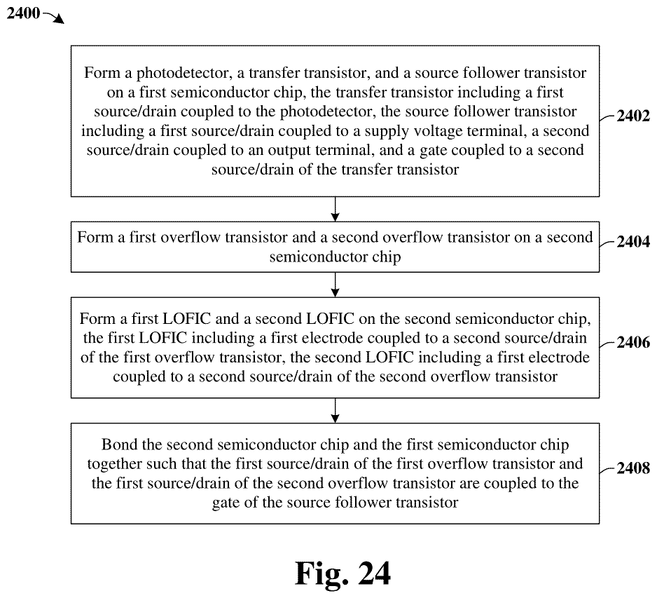

FIG. 24 illustrates a flow diagram of some embodiments of a method 2400 of forming an image sensor integrated chip including a first LOFIC and a second LOFIC coupled in parallel. While method 2400 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 2402, form a photodetector, a transfer transistor, and a source follower transistor on a first semiconductor chip. The transfer transistor includes a first source/drain coupled to the photodetector. The source follower transistor includes a first source/drain coupled to a supply voltage terminal, a second source/drain coupled to an output terminal, and a gate coupled to a second source/drain of the transfer transistor. FIG. 18 illustrates a cross-sectional view 1800 of some embodiments corresponding to block 2402.

At block 2404, form a first overflow transistor and a second overflow transistor on a second semiconductor chip. FIG. 20 illustrates a cross-sectional view 2000 of some embodiments corresponding to block 2404.

At block 2406, form a first LOFIC and a second LOFIC on the second semiconductor chip. The first LOFIC includes a first electrode coupled to a second source/drain of the first overflow transistor. The second LOFIC includes a first electrode coupled to a second source/drain of the second overflow transistor. FIG. 21 illustrates a cross-sectional view 2100 of some embodiments corresponding to block 2406.

At block 2408, bond the second semiconductor chip and the first semiconductor chip together such that the first source/drain of the first overflow transistor and the first source/drain of the second overflow transistor are coupled to the gate of the source follower transistor. FIG. 22 illustrates a cross-sectional view 2200 of some embodiments corresponding to block 2408.

Thus, the present disclosure relates to an image sensor integrated chip including a plurality of LOFICs coupled in parallel within a pixel.

Accordingly, in some embodiments, the present disclosure relates to an integrated chip including a photodetector, a transfer transistor, a source follower transistor, a first overflow transistor, a first LOFIC (lateral overflow integration capacitor), a second overflow transistor, and a second LOFIC. The transfer transistor includes a first source/drain, a second source/drain, and a gate. The first source/drain of the transfer transistor is coupled to the photodetector. The source follower transistor includes a first source/drain coupled to a supply voltage terminal, a second source/drain coupled to an output terminal, and a gate coupled to the second source/drain of the transfer transistor. The first overflow transistor includes a first source/drain, a second source/drain, and a gate. The first source/drain of the first overflow transistor is coupled to the gate of the source follower transistor. The first LOFIC includes a first electrode and a second electrode. The first electrode of the first LOFIC is coupled to the second source/drain of the first overflow transistor. The second overflow transistor includes a first source/drain, a second source/drain, and a gate. The first source/drain of the second overflow transistor is coupled to the gate of the source follower transistor. The second LOFIC includes a first electrode and a second electrode. The first electrode of the second LOFIC is coupled to the second source/drain of the second overflow transistor.

In other embodiments, the present disclosure relates to a method for forming an integrated chip. The method includes forming a photodetector and a transfer transistor along a first semiconductor substrate of a first semiconductor chip. The transfer transistor includes a first source/drain, a second source/drain, and a gate. The first source/drain of the transfer transistor is coupled to the photodetector. The method includes forming a source follower transistor along the first semiconductor substrate. The source follower transistor includes a first source/drain coupled to a supply voltage terminal, a second source/drain coupled to an output terminal, and a gate coupled to the second source/drain of the transfer transistor. The method includes forming a first overflow transistor and a second overflow transistor along a second semiconductor substrate of a second semiconductor chip. The first overflow transistor includes a first source/drain, a second source/drain, and a gate. The second overflow transistor includes a first source/drain, a second source/drain, and a gate. The method includes forming a first LOFIC (lateral overflow integration capacitor) on the second semiconductor chip. The first LOFIC includes a first electrode and a second electrode. The first electrode of the first LOFIC is coupled to the second source/drain of the first overflow transistor. The method includes forming a second LOFIC on the second semiconductor chip and spaced from the first LOFIC. The second LOFIC includes a first electrode and a second electrode. The first electrode of the second LOFIC is coupled to the second source/drain of the second overflow transistor. The method includes bonding the second semiconductor chip to the first semiconductor chip such that the first source/drain of the first overflow transistor and the first source/drain of the second overflow transistor are coupled to the gate of the source follower transistor.

In yet other embodiments, the present disclosure relates to a method for forming an integrated chip. The method includes forming a photodetector and a transfer transistor. The transfer transistor includes a first source/drain coupled to the photodetector. The method includes forming a source follower transistor including a first source/drain coupled to a supply voltage terminal, a second source/drain coupled to an output terminal, and a gate coupled to a second source/drain of the transfer transistor. The method includes forming a first overflow transistor including a first source/drain coupled to the gate of the source follower transistor. The method includes forming a first LOFIC (lateral overflow integration capacitor) including a first electrode coupled to a second source/drain of the first overflow transistor. The method includes forming a second overflow transistor including a first source/drain coupled to the gate of the source follower transistor. The method includes forming a second LOFIC including a first electrode coupled to a second source/drain of the second overflow transistor, and a second electrode coupled to a second electrode of the first LOFIC.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a photodetector;
a first transistor including a first source/drain, a second source/drain, and a gate, the first source/drain of the first transistor coupled to the photodetector;
a second transistor including a first source/drain coupled to a supply voltage terminal, a second source/drain coupled to an output terminal, and a gate coupled to the second source/drain of the first transistor;
a third transistor including a first source/drain, a second source/drain, and a gate, the first source/drain of the third transistor coupled to the gate of the second transistor;
a first capacitor including a first electrode and a second electrode, the first electrode of the first capacitor coupled to the second source/drain of the third transistor;
a fourth transistor including a first source/drain, a second source/drain, and a gate, the first source/drain of the fourth transistor coupled to the gate of the second transistor; and
a second capacitor including a first electrode and a second electrode, the first electrode of the second capacitor coupled to the second source/drain of the fourth transistor.

2. The integrated chip of claim 1, wherein the second electrode of the first capacitor is coupled to the second electrode of the second capacitor.

3. The integrated chip of claim 1, wherein the first capacitor and the second capacitor are coupled in parallel between the gate of the second transistor and a reference voltage terminal.

4. The integrated chip of claim 1, wherein the third transistor forms a first potential barrier between the gate of the second transistor and the first electrode of the first capacitor, wherein the fourth transistor forms a second potential barrier between the gate of the second transistor and the first electrode of the second capacitor, and wherein a height of the first potential barrier is different than a height of the second potential barrier.

5. The integrated chip of claim 1, further comprising:
a fifth transistor including a first source/drain, a second source/drain, and a gate, the first source/drain of the fifth transistor coupled to the gate of the second transistor; and
a third capacitor including a first electrode and a second electrode, the first electrode of the third capacitor coupled to the second source/drain of the fifth transistor.

6. The integrated chip of claim 1, wherein the photodetector, the first transistor, and the second transistor are on a first semiconductor chip, and wherein the third transistor, the fourth transistor, the first capacitor, and the second capacitor are on a second semiconductor chip bonded to the first semiconductor chip.

7. The integrated chip of claim 1, wherein the photodetector and the first transistor are on a first semiconductor chip, wherein the second transistor is on a second semiconductor chip bonded to the first semiconductor chip, and wherein the third transistor, the fourth transistor, the first capacitor, and the second capacitor are on a third semiconductor chip bonded to the second semiconductor chip.

8. The integrated chip of claim 1, further comprising:
a fifth transistor including a first source/drain, a second source/drain, and a gate, the first source/drain of the fifth transistor coupled to the first electrode of the first capacitor and the first electrode of the second capacitor, the second source/drain of the fifth transistor coupled to a reset voltage terminal.

9. The integrated chip of claim 1, further comprising:
a fifth transistor including a first source/drain, a second source/drain, and a gate, the first source/drain of the fifth transistor coupled to the first electrode of the first capacitor, the second source/drain of the fifth transistor coupled to a first reset voltage terminal; and
a sixth transistor including a first source/drain, a second source/drain, and a gate, the first source/drain of the sixth transistor coupled to the first electrode of the second capacitor, the second source/drain of the sixth transistor coupled to a second reset voltage terminal.

10. The integrated chip of claim 1, further comprising:
a control circuit having an output terminal coupled to the gate of the third transistor and the gate of the fourth transistor.

11. The integrated chip of claim 1, wherein the first capacitor is spaced over the second capacitor.

12. The integrated chip of claim 1, wherein an area between the first electrode and the second electrode of the first capacitor is different than an area between the first electrode and the second electrode of the second capacitor.

13. The integrated chip of claim 1, wherein the first capacitor is a planar capacitor, and wherein the second capacitor is a trench capacitor.

14. A method for forming an integrated chip, the method comprising:
forming a photodetector and a first transistor along a first semiconductor substrate of a first semiconductor chip, the first transistor including a first source/drain, a second source/drain, and a gate, the first source/drain of the first transistor coupled to the photodetector;
forming a second transistor along the first semiconductor substrate, the second transistor including a first source/drain coupled to a supply voltage terminal, a second source/drain coupled to an output terminal, and a gate coupled to the second source/drain of the first transistor;
forming a third transistor and a fourth transistor along a second semiconductor substrate of a second semiconductor chip, the third transistor including a first source/drain, a second source/drain, and a gate, the fourth transistor including a first source/drain, a second source/drain, and a gate;
forming a first capacitor on the second semiconductor chip, the first capacitor including a first electrode and a second electrode, the first electrode of the first capacitor coupled to the second source/drain of the third transistor;
forming a second capacitor on the second semiconductor chip and spaced from the first capacitor, the second capacitor including a first electrode and a second electrode, the first electrode of the second capacitor coupled to the second source/drain of the fourth transistor; and
bonding the second semiconductor chip to the first semiconductor chip such that the first source/drain of the third transistor and the first source/drain of the fourth transistor are coupled to the gate of the second transistor.

15. The method of claim 14, wherein the second electrode of the first capacitor is coupled to the second electrode of the second capacitor.

16. The method of claim 15, wherein the second electrode of the first capacitor and the second electrode of the second capacitor are coupled to the second semiconductor substrate.

17. The method of claim 14, further comprising:
applying a first voltage to the gate of the third transistor and applying a second voltage, different than the first voltage, to the gate of the fourth transistor while the photodetector is illuminated.

18. The method of claim 14, further comprising:
forming a fifth transistor along the second semiconductor substrate of the second semiconductor chip, the fifth transistor including a first source/drain, a second source/drain, and a gate, the first source/drain of the fifth transistor coupled to the first electrode of the first capacitor, the second source/drain of the fifth transistor coupled to a reset voltage terminal.

19. A method for forming an integrated chip, the method comprising:
forming a photodetector and a first transistor, the first transistor including a first source/drain coupled to the photodetector;
forming a second transistor including a first source/drain coupled to a supply voltage terminal, a second source/drain coupled to an output terminal, and a gate coupled to a second source/drain of the first transistor;
forming a third transistor including a first source/drain coupled to the gate of the second transistor;
forming a first capacitor including a first electrode coupled to a second source/drain of the third transistor;
forming a fourth transistor including a first source/drain coupled to the gate of the second transistor; and
forming a second capacitor including a first electrode coupled to a second source/drain of the fourth transistor, and a second electrode coupled to a second electrode of the first capacitor.

20. The method of claim 19, further comprising:
forming a control circuit having an output terminal coupled to a gate of the third transistor and a gate of the fourth transistor.
